(19) United States
(12) Patent Application Publication
(10) Pub. No.: US 2016/0187395 A1
(43) Pub. Date: Jun. 30, 2016

(54) FORECAST FOR DEMAND OF ENERGY

(71) Applicant: Intel Corporation, Santa Clara, CA (US)

(72) Inventors: Devadatta V. Bodas, Federal Way, WA (US); Muralidhar Rajappa, Chandler, AZ (US); Justin J. Song, Olympia, WA (US); Andy Hoffman, Olympia, WA (US)

(73) Assignee: INTEL CORPORATION, Santa Clara, CA (US)

(21) Appl. No.: 14/582,988

(22) Filed: Dec. 24, 2014

(51) Int. Cl. G01R 21/00; G06F 11/30

(52) U.S. Cl. CPC G01R 21/00; G06F 11/3006; G06F 11/3062

(57) ABSTRACT

A system and method for forecasting power consumption at a facility, the facility having a system of compute units for executing jobs of computing. The forecast of power includes forecasting sequence of jobs execution on a system of the nodes over time, estimating power for the jobs of the system, and developing a system-level power forecast.

### CROSS-REFERENCE TO RELATED APPLICATIONS

The present application is related to the U.S. patent application Ser. No. ______ (Attorney Docket No. 42P73498) entitled ______ filed ______; the U.S. patent application Ser. No. ______ (Attorney Docket No. 42P74562) entitled ______ filed ______; the U.S. patent application Ser. No. ______ (Attorney Docket No. 42P74566) entitled ______ filed ______; the U.S. patent application Ser. No. ______ (Attorney Docket No. 42P74567) entitled ______ filed ______; the U.S. patent application Ser. No. ______ (Attorney Docket No. 42P74568) entitled ______ filed ______; the U.S. patent application Ser. No. ______ (Attorney Docket No. 42P74569) entitled ______ filed ______; the U.S. patent application Ser. No. ______ (Attorney Docket No. 42P74564) entitled ______ filed ______; the U.S. patent application Ser. No. ______ (Attorney Docket No. 42P74565) entitled ______ filed ______; and the U.S. patent application Ser. No. ______ (Attorney Docket No. 42P74570) entitled “Computational Unit Selection” filed ______.

### TECHNICAL FIELD

The present techniques relate generally to distributed computing. More particularly, the techniques relate to power forecasting of distributed computing.

### BACKGROUND ART

High Performance Computing (HPC) and distributed computing may facilitate scientists and engineers to solve complex science, engineering, and business problems using applications that benefit from high bandwidth, low latency networking, and very high compute capabilities. Such HPC systems may also execute data storage and retrieval, perform more straightforward tasks, and so on. Unfortunately, HPC systems, which generally have thousands of compute nodes performing tasks, typically consume significant power. Such may be especially problematic in the “Big Data” era. Further, variations in power consumption and issues of power allocation may also be problematic.

The competitive business of data and computing services drives manufacturers in the continuous improvement of their processes and products in order to lower production costs and deliver reliable service. Indeed, as technologies advance in services for data, computing, and telecommunications, a competitive need exists to continuously increase consistency of service and the efficiency of power utilization.

### BRIEF DESCRIPTION OF DRAWINGS

FIG. 1 is a diagrammatical representation of an exemplary distributed computing facility in accordance with embodiments of the present techniques.

FIG. 2 is a job-sequence diagram depicting jobs running on a system of nodes over time in accordance with embodiments of the present techniques.

FIG. 3 is a power diagram of power consumption of the system of FIG. 2 executing the sequence of jobs over time in accordance with embodiments of the present techniques.

FIG. 4 is a power diagram of power consumption of the system of FIGS. 2 and 3 executing the sequence of jobs over time, including the use of local generation in accordance with embodiments of the present techniques.

FIG. 5 is a block diagram depicting an example of a tangible non-transitory, computer-readable medium that can facilitate power forecasting in accordance with embodiments of the present techniques.

FIG. 6 is a block flow diagram of a method of forecasting power consumption at a distributed computing facility in accordance with embodiments of the present techniques.

FIG. 7 is a method of forecasting power consumption a facility, such as a distributed computing facility, in accordance with embodiments of the present techniques.

FIG. 8 is a diagram of an example facility for distributed computing having multiple HPC systems of nodes for computing, in accordance with embodiments of the present techniques.

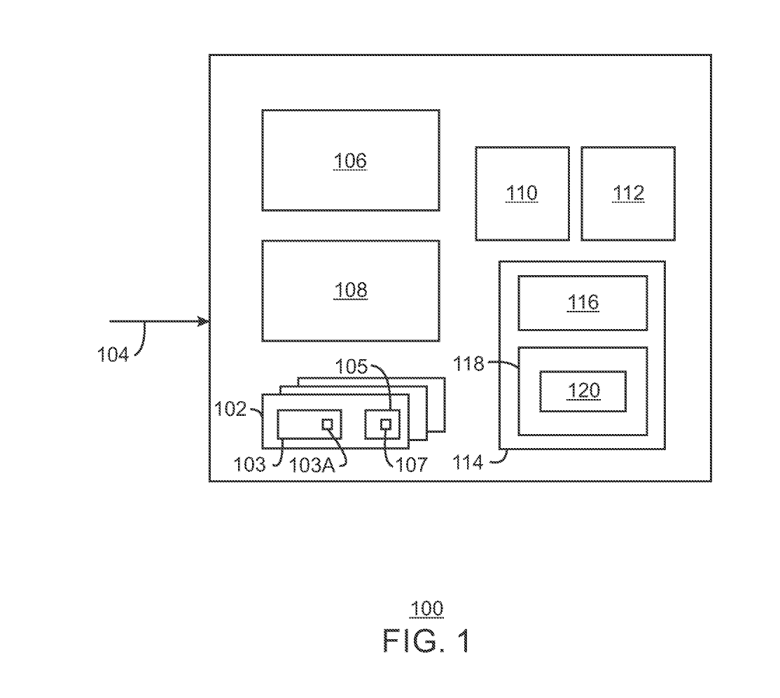

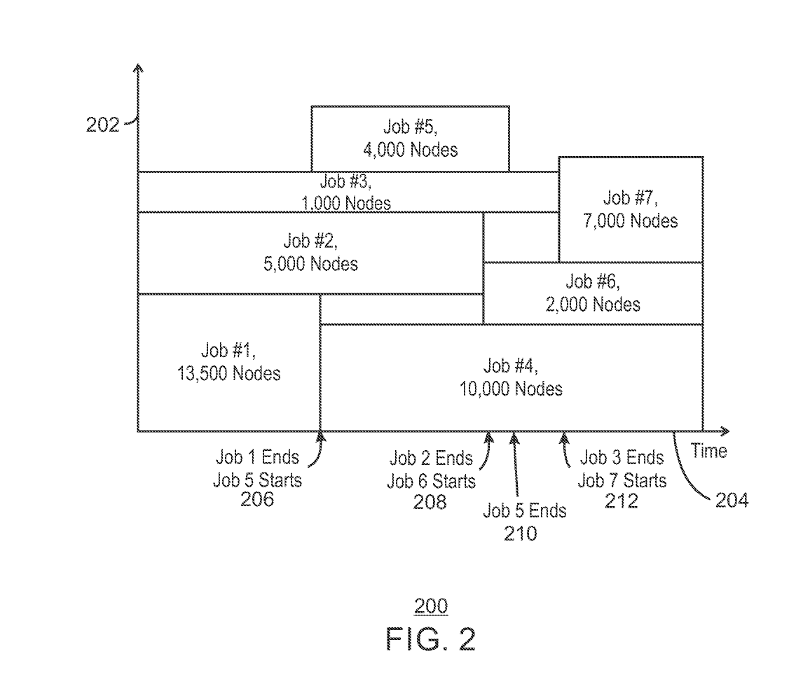

The same numbers are used throughout the disclosure and the figures to reference like components and features. Numbers in the 100 series refer to features originally found in FIG. 1; numbers in the 200 series refer to features originally found in FIG. 2; and so on.

### DETAILED DESCRIPTION

FIG. 1 is a diagrammatical representation of a distributed computing facility 100, such as an HPC facility, Big Data analytics facility, datacenter, telecommunications center, and so on. The depiction of the computing facility 100 may represent a single facility or multiple facilities across geographical locations. In the illustrated embodiment, the distributed computing facility 100 has nodes 102. In examples, the number of nodes 102 may be as many as 2, 4, 16, 100, 1,000, 2,000, 5,000, 10,000, 20,000, 40,000, 60,000, 100,000, and 1,000,000, or greater. In certain embodiments, the nodes 102 may generally be compute nodes and also include operating system (OS) nodes, input/output (I/O) nodes, and so on.

Each compute node 102 typically includes one or more processors 103, such as a central processing unit (CPU). Indeed, each node 102 may have a CPU processor package including multiple processors 103. Further, each processor 103 has one or more processing cores 103A. For example, a processor 103 may have ten cores 103A. In addition, each node 102 may have memory 105 storing code 107 (i.e., logic, modules, instructions, etc.) executable by the processor 103 or other processor. The code 107 may include a node manager, job manager, and the like, to facilitate execution of tasks and adjustment of the tasks with respect to power and performance. The nodes 102 may include other hardware, software, and firmware, may be housed in racks, for example, and may be grouped into systems or groups of nodes 102, and so forth.

The facility 100 receives power, as indicated by reference numeral 104. The power may be electricity received from one or more electricity providers such as a utility company. As can be appreciated, the compute nodes 102 and other computing devices in the facility 100 generally require power or electricity as electronic devices in computing and executing tasks. Further, other systems such as lighting and cooling systems, represented by blocks 106 and 108, respectively, may consume power. Moreover, in certain embodiments, the facility 100 may include alternate or local power generation systems 110 (e.g., diesel generators, etc.) and/or battery or energy storage systems 112.

In addition, the facility 100 generally includes one or more computing devices 114 (e.g., servers) which may be disposed locally within the facility 100 and/or remote to the facility 100. The computing device(s) 114 may include one or more processors 116 (e.g., CPU) and memory 118. Various manager modules or code 120 may be stored in the memory 118 and executable by the processor(s) 116. For example, the executable code 120 and/or the aforementioned executable code 107 on the nodes 102 may include a job manager that may assign and manage tasks across the compute nodes 102, including with respect to power consumption. Other examples of manager modules in the server executable code 120 and/or in the node executable code 107 include a facility power manager, resource manager, system power performance managers (e.g., for groups of nodes), rack managers, node managers, and so on. Moreover, a compute node can be a server or a board, and/or several compute nodes may be on one board.

It should be noted that while the discussion in this disclosure may at times focus on datacenters, it should be understood that the term “datacenter” as used herein can refer to a variety of distributing computing facilities and configurations. For example, a distributed computing facility or datacenter may be high performance computing (HPC), Big Data analytics, search engine facility, telecommunications center, web services center, cloud computing facility, data processing facility, and so forth.

Demand for energy in datacenters is growing. Many energy producers or utility providers are unable to meet this growing demand. This problem is experienced throughout the world. Datacenters are generally built to be used ten years or more. Traditionally, datacenter demand for allocation of power may be governed by maximum power need of the data center over a period of 2-3 years, for example. As a result, actual use of power at the datacenter may be significantly lower than allocation.

Utility companies may rely on several different ways of generating power including nuclear, hydro, coal, diesel, geothermal, wind, solar, etc. Most high capacity generators generally have long start-up and shut-down times. Electrical energy must generally be consumed the moment it is generated. These limitations may require that utility companies have a good forecast on demand for energy to manage multiple sources of energy generation. Conventionally, these demands are communicated manually and a forecast is done months in advance. Both of these factors drive conservative and inaccurate forecasts.

A problem is high operational cost. The cost of energy for a datacenter may be divided into at least two parts: meter charge and demand charge. When datacenters do not use allocated power, the utility demand charge can become significant. Another problem is low energy efficiency for the electricity providers. In other words, because of the aforementioned problems with forecasting and allocation, generated power is not diverted as per plan by the utility companies. Therefore, the efficiency of the power or electricity grid may be poor. Yet another problem for the utility provider (and problem and possible opportunity for the user facility) is wild swings in pricing of energy. Utility companies and suppliers try to sell excess energy on the energy market. Usually, they have to sell excess energy at a significant discount rate. On the other hand, when user demand exceeds the forecast, the user consequently buys scarce energy at a premium price. In all, there is a generally very wide variation in pricing of energy, such as from $125 per megawatt-hour (MWh) to sometimes close to zero. This generally causes an enormous challenge to price control.

An interface to facilitate users (e.g., datacenters) to change their specified demand and take advantage of energy spot pricing may be beneficial to the user. Such may be especially beneficial to the user if the user can negotiate this change in specified demand every day, every few hours, or every few minutes. In all, the aforementioned power supply, allocation, and pricing issues call out for better forecast and automation to facilitate just-in-time supply of energy.

In some embodiments, a facility such as datacenter or other distributed computing facility, may use mechanisms including automated mechanisms, to negotiate demand and allocation with energy producers and utility companies or providers. Example techniques that may be implemented include methods and systems to: (1) develop energy forecast on a regular (i.e., frequent) basis, (2) adjust level of demand (including negotiated specified demand) as well as source of energy based upon incentive programs and spot pricing of the energy, and (3) adjust use of local energy generation and storage based on changing demand and pricing.

Traditionally, a forecast for power is based upon power and cooling capability of the datacenter. For example, a datacenter with a system of 20,000 nodes (e.g., compute nodes), and power need capability (computing, cooling, lighting, etc.) of 7.5 megawatt (MW), may ask for an allocation of 7.5 MW. However, actual power consumption at the datacenter in this example may vary between 2.5 MW to 7.3 MW, resulting in unused, wasted, and/or stranded power. Further, the datacenter may have capability to generate power. In this example, the production capability is to generate 4 MW with diesel generators and 0.5 MW from solar. Conventionally, these generation resources and investment may be beneficial in protecting against power supply failure but not to help reduce the cost of energy.

FIG. 2 is a job-sequence diagram 200 depicting jobs 202 (e.g., HPC jobs) running (executing) on a system of nodes (e.g., HPC system) over time 204. In the illustrated example, the HPC system has 20,000 nodes, and the HPC system jobs 200 include Job #1, Job #2, Job #3, Job #4, Job #5, Job #6, and Job #7. At the initial time 204, Job #1, Job #2, and Job # 3 start or are already running. Over the time 204, Job #4, Job #5, Job #6, and Job #7 start, and Job #1, Job #2, Job #3, and Job #4 reach completion. Again, the diagram 200 illustrates am exemplary sequence of job execution of jobs on an HPC system having 20,000 nodes. The number of nodes per job (at which the job executes) is noted in the job boxes.

The arrow 206 indicates the time 204 at which Job #1 ends, Job #4 starts, and Job #5 starts, and in which the number of nodes executing jobs in the HPC system changes from 19,500 nodes to 20,000 nodes. Thus at this point in time, all nodes of the HPC system are executing jobs, performing computation. Then, the arrow 208 indicates the time 204 that Job #2 ends and Job #6 starts, and in which the number of nodes executing jobs changes from 20,000 nodes to 17,000 nodes. Arrow 210 notes the time 204 that Job #5 ends and the number of nodes executing jobs decreases from 17,000 nodes to 13,000 nodes. Lastly, the time 204 at which Job #3 ends and Job #7 starts is indicated at arrow 212. At this point in time 204, the number of executing nodes of the HPC system increases from 13,000 nodes to 19,000 nodes.

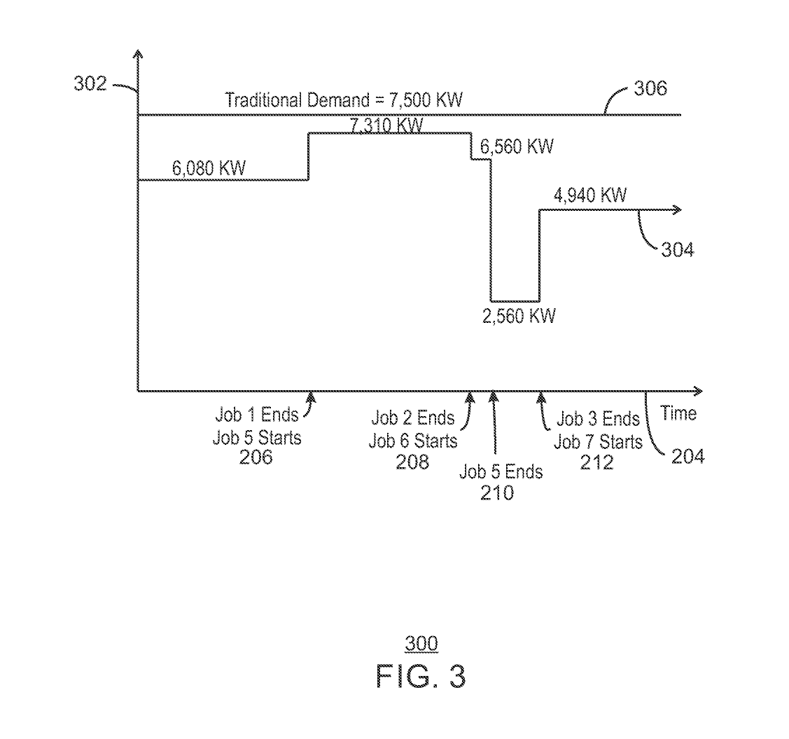

FIG. 3 is a power diagram 300 (e.g., a forecast) of power consumption 302 in kilowatts (kW) of the system of FIG. 2 executing the sequence of jobs over time 204. The arrows 206, 208, 210, 212 from FIG. 2 noting start and end times of jobs are given in FIG. 3.

The power curve 304 notes the power consumption of the HPC system over time 204. Numerical values of the power consumption in this example are listed. For instance, the system power consumption at the beginning of the time 204 and for a time period thereafter is 6,080 KW as listed. A change in power is realized at the time 204 point noted by arrow 206, and in which the facility or HPC system power increases to 7,310 KW. Then, the power further changes through the sequencing of the jobs. The power curve 304 may be the actual implemented power consumption of the jobs as executed and/or may be forecasted power consumption of the HPC system prior to actual execution of the jobs.

A specified allocated demand 306 for the HPC system, as negotiated with a utility provider, for example, does not change over the depicted time 204. In the illustrated example, the specified allocated demand is 7,500 KW. The difference between the allocated demand 306 line and the power curve 304 may represent energy allocated but unused. The depicted allocated demand 306 may be traditional in a sense that this specified or allocated demand 306 remains the same and is not renegotiated over shorter periods of time.

An aspect of embodiments of the present techniques may use the power curve 304 from job sequencing to communicate a forecast of demand to the utility provider. The forecast may give a more accurate amount of power needed for the facility or the HPC system than specified allocation. Some embodiments of this forecasting do not consider or add use of any local power storage or generation, for example. In all, these types of power forecasts base on job sequencing, for example, and the further actions of related communication with the utility provider or supplier, may help the datacenter to keep its demand charge lower.

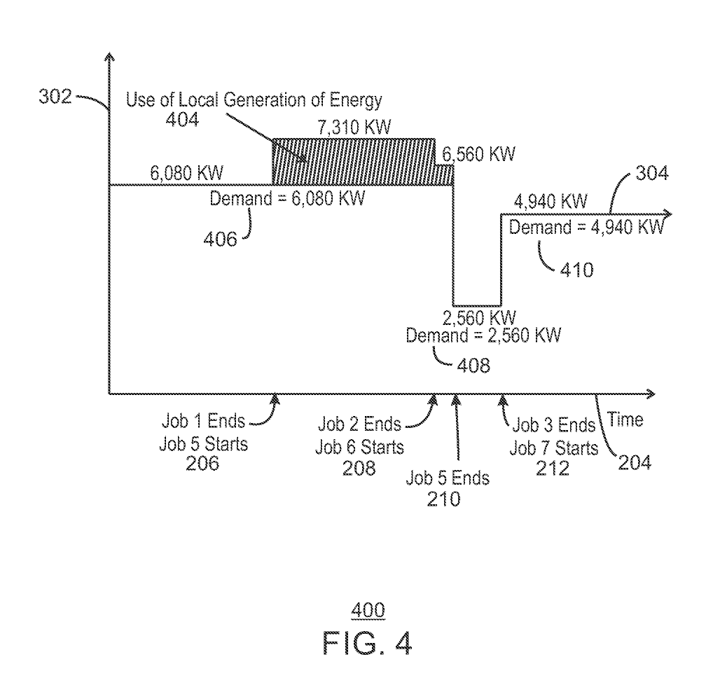

Additionally, in certain embodiments, local energy may be employed to keep demand low. The use of local energy may reduce both demand charge and meter charge for energy. Furthermore, the use of local energy may facilitate adjustment of actual demand and/or specified demand to take advantage of incentive programs offered by the utility provider, and to pursue other business opportunities with respect to electrical supply pricing, for instance. The local energy generation may include non-renewable energy generation such as with diesel generators, and also include renewable energy generation such as with solar, wind, geothermal, and so forth. FIG. 4 represents demand comprehending local generation of energy.

FIG. 4 is a power diagram 400 (e.g., a forecast) of power consumption 302 in kilowatts (kW) of the system of FIGS. 2 and 3 executing the sequence of jobs over time 204. The arrows 206, 208, 210, 212 from FIGS. 2 and 3 noting start and end times of jobs are given in FIG. 4. In the illustrated embodiment, the power curve 304 is affected by the use of local generation of energy, as indicated by region 404. While the actual power consumed by the facility or HPC system may rise from 6,080 KW to 7,310 KW, the amount of actual demand of power consumed from the utility provider remains at 6,080 KW due to use of local generation of energy. Thus, an allocated demand 406 could be 6,080 KW without incurring a demand charge. Plus, the meter charge will be less. The subsequent demands 408 and 410 (2,560 KW and 4,940 KW) match the power curve 304.

Some embodiments may employ an estimator module to estimate power and time-to-completion of distributed computing job. Such an estimator tool that estimates power of job may be employed in order to develop a power forecast for the datacenter. The estimator may utilize data provided by a calibrator, for example, that calibrates nodes of the datacenter. The estimator may rely, in part, on such a calibrator to develop a power estimate for both maximum power and average power needed for a job. As for output, the estimator may also provide an estimate for how long (time) the job may take to complete.

Embodiments herein may also rely on or accommodate estimating sequence of job execution. In particular, a software utility or job forecaster may help a system resource manager to develop a sequence, for example. Conventionally, a resource manager may schedule and launch jobs based upon a number of factors, such as priority of jobs, available nodes, required nodes, etc. However, a job forecaster may in addition, model these actions and actors to develop a sequence. The FIG. 3 discussed above may be an example output from a job forecaster.

In some embodiments, a new power forecast (energy forecast) may be developed every time (or nearly every time) there is an occurrence of either a job-related event, i.e., job event, or an energy event. Examples of job-related events include a user submitting a job, reshuffling in priority of jobs, or start of a job, when a running job completes, crashes or is suspended. Examples of energy events include change in status or capacity of local generation of energy, change in capacity of local storage of energy, or change in pricing of energy beyond predefined thresholds.

In sum, a job event, an energy event, or other event, may trigger generation and reevaluation of the energy forecast for the facility. In implementation, upon the occurrence of a job event or an energy event, stored executable code (e.g., a facility power manager) may initiate and update a facility energy forecast. As a part of generation of such a forecast, the facility power manager may ask for an up-to-date energy forecast from each system located in the facility. In some examples, the update of the energy forecast is initiated in response to job event or energy event, plus an additional factor or criterion.

In general, embodiments are directed to forecasting power demand for a datacenter. An estimator determining power estimates of jobs, and a job forecaster further considering job sequencing and other factors, may provide for input to develop a forecast for demand for the datacenter. This forecast may also generally comprehend other energy consumers at the datacenter, such with respect to power conversion efficiency, cooling systems, building lighting, etc. The forecast developed may be a baseline forecast which can be modified to comprehend the following to reduce cost of energy: (1) consideration of utility incentive programs such with respect to time of the day, (2) use of renewable energy, (3) use of local energy storage and generation, (4) spot pricing of the energy, and so forth.

Datacenters that host HPC systems will continue to increase in energy consumption. The specified allocated power demand with the utility provider may reach as much as 40-45 MW and greater. However, at times during such high allocation, the actual demand or consumption of energy at the datacenter may commonly be lower that the specified demand allocation. Thus, as discussed, techniques for developing power forecasts and automated adjustment of specified demand may be beneficial.

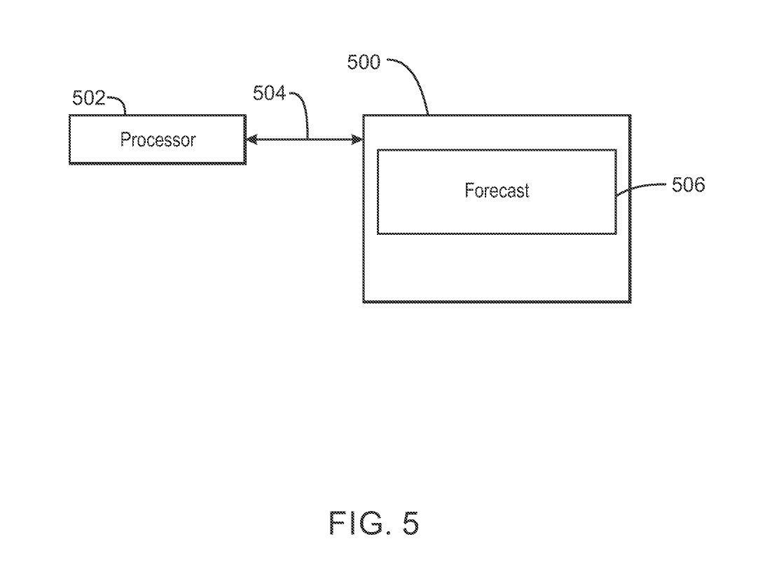

FIG. 5 is a block diagram depicting an example of a tangible non-transitory, computer-readable medium that can facilitate power forecasting and management with respect to a distributed computing system and facility in accordance with embodiments of the present techniques. The computer-readable medium 500 may be accessed by a processor 502 over a computer interconnect 504. The processor 502 may be one or more compute node processors (e.g., 103), a server processor (e.g., 116), or another processor. The tangible, non-transitory, computer-readable medium 500 may include executable instructions or code to direct the processor 502 to perform the operations of the techniques described herein.

The various software components discussed herein may be stored on the tangible, non-transitory, computer-readable medium 500, as indicated in FIG. 5. For example, a power forecast module 506 (executable code/instructions) may direct the processor 502 to determine power consumption and demand for a distributed computing system and at a distributed computing facility. The code or module 506 may be similar or the same as the aforementioned executable code 107, 120 in FIG. 1. It should be understood that any number of additional software components not shown in FIG. 5 may be included within the tangible, non-transitory, computer-readable medium 500, depending on the application.

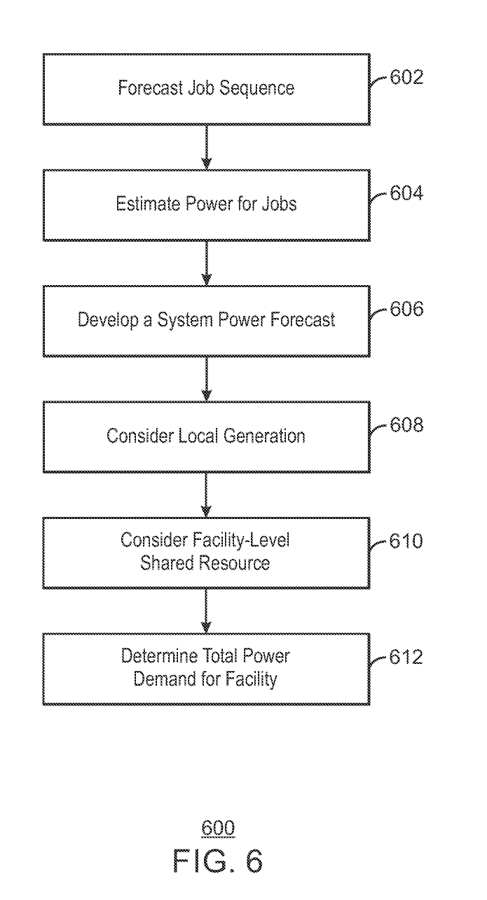

FIG. 6 is a method 600 of forecasting power consumption a distributed computing facility. The distributed computing facility may have nodes for executing jobs of distributed computing. The method 600 may be performed by a computer, a processor, a node, and so on.

To forecast power consumption at the facility, the sequence of job execution on a system of nodes may be estimated (block 602). Further, the power of the jobs on the system may be estimated (block 604). To estimate the power of the jobs to run on the system of nodes, the following may be employed or considered: (1) use of historical data scaled based upon nodes; (2) node power including average and maximum power; (3) shared power such as that associated with networking, file systems, and so on; (4) losses in power and energy efficiency. Of course, other factors may be considered for job and system-level power.

The method 600 includes developing (block 606) a power profile or power forecast of the system of nodes. The power profile(s) or power forecast may be a maximum power profile, an average power profile, and so forth. As discussed above, the power profile or power forecast at the system level may be based on or correlative with the forecasted sequence of job execution and the estimated power for the jobs. Further, for facility-level power estimating, the method 600 may further consider (block 608) local generation and/or local storage of energy, as well as facility-level energy consumers (e.g., shared resources such as lighting and cooling), in addition to the systems-level power estimate or forecast. It should be noted, that the consideration (block 608) may involve actively adjusting operation of the local generation or storage.

Lastly, the method includes determining (block 610) total actual power demand by the distributed computing facility. The total actual power demand to the utility provider(s) may be the forecasted power consumption of the facility minus any local generation of power, for example. The total actual demand may be based, in part, on the sum of the power consumption of one or more systems of nodes at the distributed computing facility. Moreover, the determining (block 610) of the total actual power demand may involve active adjustments of actual power demand such as via implementation of local energy generation or storage.

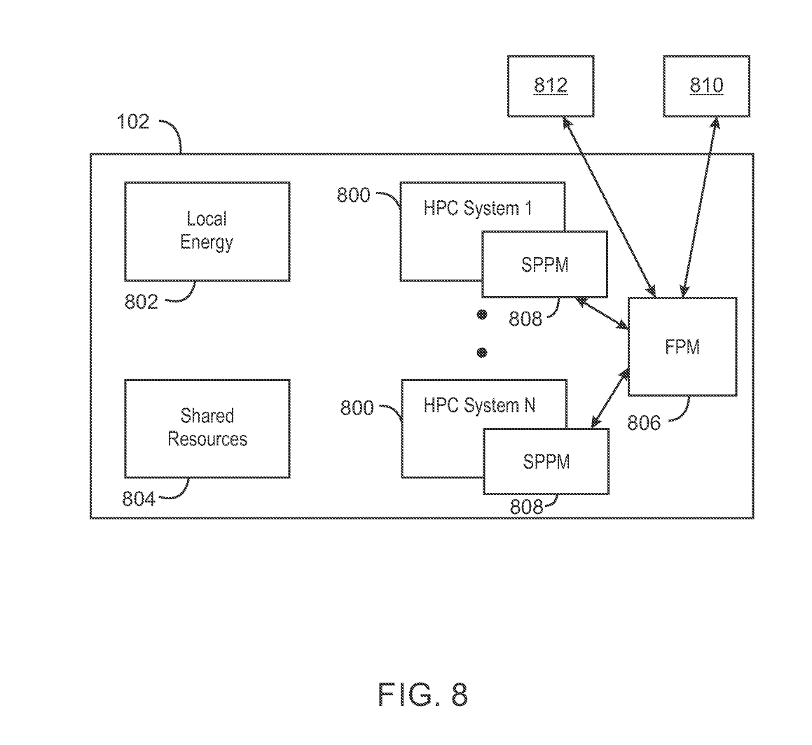

With respect to system level for the power or energy forecast, the estimator in developing (block 606) a system power forecast may estimate power needs for a job. A system power performance manager (SPPM) (see, e.g., FIG. 8), for example, may generate an estimate forecast for power needs for a system of nodes or compute units, executing multiple jobs. To develop such a system-level forecast, the SPPM in addition to the system computing power demands, may comprehend system-level overhead such as losses in the shared power and cooling infrastructure, and power needs for system level shared resources such as storage systems, networking infrastructure, and so on.

As for the facility level, a facility power manager (FPM), for example, may generate an energy or power forecast using power forecasts for all the systems in the facility or datacenter. The FPM may need to account for systems that do not have capability to develop a system forecast. For such systems, the FPM may use historical information of usage of power or use traditional approach of worst case power demand. The FPM will typically also comprehend losses in facility level power conversion and cooling, for instance. Further, the FPM will generally account for power usage by shared resources at facility level. Examples of such shared resources are office area and building management system lighting and cooling.

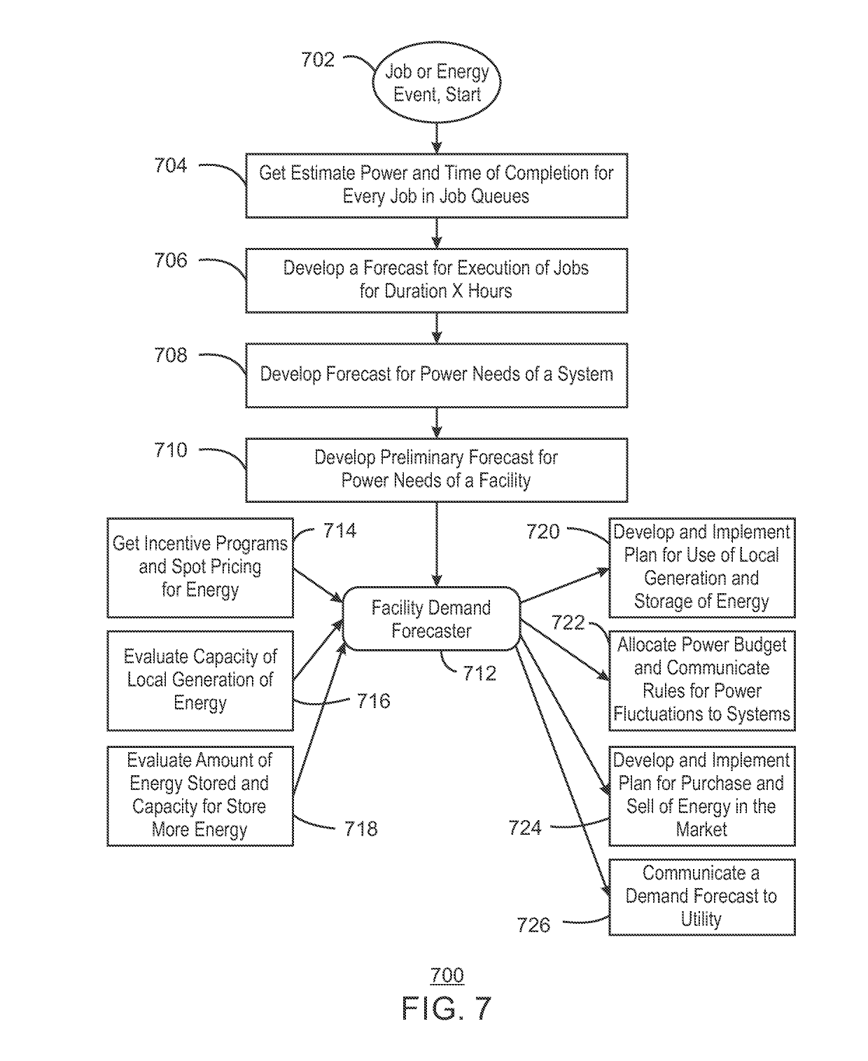

FIG. 7 is a method 700 of forecasting power consumption a facility, such as a distributed computing facility. The development, reevaluation, or update of a power forecast may be initiated (block 702) by a job event or energy event, for example. For an HPC system of nodes, for example, the power and time of completion for most or all jobs in the system job queues may be estimated (block 704). Thus, energy or power forecast for the execution of the jobs for duration of X hours may be developed (block 706). Then, a forecast for power needs of the system may be developed (block 708). Such may include energy consumption via shared resources at the system level.

At the facility level, a preliminary forecast for power needs of the facility may be determined (block 710). This demand may be based upon forecast of power for most or all systems in the facility. This preliminary forecast for the facility may be developed by or fed to a facility demand forecaster 712 (module or executable code). Then, the facility demand forecaster 712 may consider other factors. For example, the forecaster 712 may consider incentive programs and spot pricing for energy (block 714), capacity of local generation of energy (block 716), and the amount of energy stored and the capacity to store more energy (718). Of course, the facility demand forecaster 712 may consider additional information and other factors.

The output of the facility demand forecaster 712 may be to develop and implement a plan for use of local generation and storage of energy (block 720), a plan for purchase and sell of energy in the market (block 724), and other plans. Further, as noted by block 722, the forecaster 712 may allocate a power budget may communicate rules for power fluctuations to systems. Indeed, the forecaster 712 output may include various communications. For example, the output may be to communicate (block 426) a demand forecast for the facility to the utility, i.e., the utility company or provider. Lastly, it should be noted that the facility demand forecaster 712 may be directed by or part of a facility power manager (FPM).

FIG. 8 is an example facility 102 for distributed computing having multiple HPC systems 800 of nodes for computing. As can be appreciated, such computing consumes power. Other consumers of power at the facility 102 may be shared resources 804, such as cooling, lighting, and other shared resources and other consumers. Additional facility consumption in power may also include efficiency losses with respect to power conversion, for example, and by other users or consumers at the facility. As for receipt of energy, the power supplied to the facility 102 from a utility company or distributor may be supplemented by generation and/or the storage of local energy 802. The generation of local energy 802 can be performed for multiple reasons including power ramp and band control, reducing changes in demand for energy (demand communicated from facility to utility company), decrease cost of energy by generating locally when utility cost is high, develop revenue by selling locally generated energy when cost of energy is high by the utility company or on the market, and so forth. It should be noted with respect power ramp control, utility providers may dictate that fluctuations in power consumption are to be controlled and occur at slow rates. A power ramp control referring to techniques to dampen a sudden change in power consumption, for example to an acceptable level or more gradual change. With respect to power band control, utility providers may expect facilities to maintain power consumption within a range of allocation. That is if allocated power is 10 MW, the utility provider may expect power consumption by the facility be between 8 to 10 MW. These minimum and maximum levels of power may be referred to as power band.

A facility power manager (FPM) 806 may develop a power forecast for the facility. To develop, reevaluate, or update the facility power forecast, the FPM 806 may communicate with a system power-performance manager (SPPM) 808 at each system 800 of nodes to comprehend system-level computing power needs and system-level shared-resource power needs. The SPPM 808 will generally determine or update system-level power forecasts/profile for sequencing and power estimates of distributed computing jobs, as discussed above. Of course, the SPPM 808 may be involved with or direct a variety of power-performance issues and controls at the system level.

To develop or update the facility power forecast, the FPM 806 will also consider facility-level consumers including shared resources 804 (lighting, etc.) and local energy 802 generation/storage at the facility level, as discussed. The FPM 806 may develop or determine a value for total power demand for the facility 102. This value for power demand may be communicated from the FPM 806 to the utility company 810 (provider, distributer, supplier, etc.) supplying electricity (power) to the facility 102. Of course, the FPM 806 may be in communication with the utility company 810 regarding other issues. Moreover, in the illustrated embodiment, the FPM 806 may be in communication with a facility manager or administrator 812, for instance. This communication may involve, for example, facility rules and policies, including with respect to power.

In addition to forecasting power and developing or updating demand, the FPM 806 may be involved in a variety of other facility controls. The FPM 806 gives direction to the multiple system managers SPPM 808 for the systems 800 of nodes. Further, again, the FPM 806 may communicate with and have policies/rules set with a human administrator 812, utility company or provider 810, and so forth. In examples, the FPM 806 may be or use a demand/response interface to the utility provider 810. Moreover, the FPM 806 may perform accountings of power and cooling at the facility 102, and the like, including to communicate capacity and requirements. The FPM 806 may account for a cooling system (of 804), manage generation of local energy 802, allocate power budgets to the one or more SPPM 808, and so forth.

A FPM 806 may use various mechanisms to meet requirements by the datacenter operator with respect to power consumption variation, such as for delta Watts per minute (ΔW/min) and ΔW/hour. A datacenter operator may also have the FPM 806 maintain facility-level power consumption at, or slightly below, power allocation by the utility provider 302. With targets to keep energy efficiency high, the FPM 806 may attempt to employ green mechanisms before resorting to non-green mechanisms.

For a facility 102 with generators of local energy 802, the FPM 808 may use local energy 802. Depending on the particular facility 102, there may be various types of local generators of energy. Examples of local generators are diesel engines, solar power, and so forth. In a particular example, if facility 102 demand for power as negotiated with the utility provider 810 is set at say 12 MW, and the facility 102 has local power 802 generation of 2 MW, for instance, then the facility 102 may instead renegotiate demand for 10 MW from the utility provider 810. If so, the utility provider 810 may require the facility 102 draw from the utility provider 810 between 8.5 MW to 10 MW (e.g., allowed variation of 15%), for example. In this numerical example, the 2 MW local energy 802 generation may facilitate datacenter facility 102 level fluctuation between 8.5 to 12 MW (˜30% variation). Local power generation may therefore increase flexibility or level of power, as well as help meet goal(s) for limited variation (e.g., ΔW/hour) over the long term.

For a facility 102 with local power 802 storage, the FPM 808 may use the power 802 storage (e.g., battery, local refrigeration, etc.). When facility 102 level actual power consumption may fall below minimum demand (say 8.5 MW in the above numerical example), the FPM 808 may channel energy to charge batteries 140 part of the local energy 802. The resulting battery charge may later then be used when facility 102 actual demand for power grows. Another approach for energy 802 storage is to use excess energy (e.g., when actual power consumption of the facility drops below negotiated demand) to cool liquid or to generate ice. Ice or cool liquid can be stored and used later for savings in energy in the cooling system (e.g., of 804) when actual power consumption exceeds demand. Other examples of mechanisms the FPM 808 may employ is for the FPM 808 to designate settings on the cooling systems (e.g., a shared resource 804), such as adjusting the temperature or temperature set point of coolant, air, or water in the cooling system. Such control may affect power consumed by both the cooling system and the computing architecture of the systems 800.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine, e.g., a computer. For example, a machine-readable medium may include read only memory (ROM); random access memory (RAM); magnetic disk storage media; optical storage media; flash memory devices; or electrical, optical, acoustical or other form of propagated signals, e.g., carrier waves, infrared signals, digital signals, or the interfaces that transmit and/or receive signals, among others.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the present techniques. The various appearances of “an embodiment,” “one embodiment,” or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

Examples are provided. Example 1 is a distributed computing facility including nodes configured to execute jobs of distributed computing. The distributed computing facility includes memory storing code executable by the nodes or a processor to forecast power consumption by the distributed computing facility, including to forecast sequence of jobs execution on a system of the nodes over time, estimate power for the jobs of the system, and develop a system-level power forecast of the system.

Example 2 incorporates the subject matter of Example 1. In this example, the system-level power forecast comprises a predicted power profile correlative with the sequence of job execution and the power for the jobs.

Example 3 incorporates the subject matter of any combination of Examples 1-2. In this example, the code is executable to activate or increase local energy generation in response to the forecast of power consumption exceeding a specified demand.

Example 4 incorporates the subject matter of any combination of Examples 1-3. In this example, to forecast power consumption comprises to develop a forecast of total actual demand for the distributed computing facility.

Example 5 incorporates the subject matter of any combination of Examples 1-4. In this example, to develop the forecast of total actual demand comprises considering local power generation at the distributed computing facility.

Example 6 incorporates the subject matter of any combination of Examples 1-5. In this example, the total actual demand comprises the power consumption minus an amount of local power generated at the distributed computing facility.

Example 7 incorporates the subject matter of any combination of Examples 1-6. In this example, to forecast power consumption comprises to forecast power consumption in response to a job event or an energy event, or a combination thereof.

Example 8 incorporates the subject matter of any combination of Examples 1-7. In this example, the job event comprise submission of a job for execution to the system, completion of a job on the system, suspension of a job on the system, or any combination thereof.

Example 9 incorporates the subject matter of any combination of Examples 1-8. In this example, the energy event comprises a change in status or capacity of local generation of energy, change in capacity of local storage of energy, or change in pricing of energy beyond predefined thresholds, or any combination thereof.

Example 10 incorporates the subject matter of any combination of Examples 1-9. In this example, the code is executable to adjust total actual demand of power by the distributed computing facility by adjusting use of local energy generation or energy storage, or both, at the distributed computing facility.

Example 11 incorporates the subject matter of any combination of Examples 1-10. In this example, the code is executable to adjust use of local energy generation or energy storage, or both, at the distributed computing facility in response to changing demand of power or changing pricing of energy, or both.

Example 12 incorporates the subject matter of any combination of Examples 1-11. In this example, the code is executable to adjust total actual demand of power by the distributed computing facility in response to an incentive program by a utility provider or in response to spot pricing of energy, or a combination thereof.

Example 13 incorporates the subject matter of any combination of Examples 1-12. In this example, the distributed computing facility comprises a high performance computing (HPC) facility or a Big Data analytics facility, or a combination thereof, and wherein to forecast power consumption comprises to forecast power consumption in response to a job event or an energy event, or a combination thereof.

Example 14 is a method of operating a distributed computing facility, the method including executing jobs of distributed computing on systems of nodes of the distributed computing facility. Further, the method includes forecasting, via a processor, power consumption of the distributed computing facility, wherein forecasting the power consumption includes: forecasting, via the processor, a sequence of jobs execution on a system of the nodes over time; estimating, via the processor, power for the jobs of the system; and developing, via the processor, a system-level power forecast of the system.

Example 15 incorporates the subject matter of Example 14. In this example, the system-level power forecast comprises a predicted power profile correlative with the sequence of job execution and the power for the jobs.

Example 16 incorporates the subject matter of any combination of Examples 14-15. In this example, the method includes activating or increasing local energy generation at the distributed computing facility in response to a forecast of the power consumption exceeding a specified demand.

Example 17 incorporates the subject matter of any combination of Examples 14-16. In this example, the forecasting power consumption includes forecasting total actual demand to a utility provider for the distributed computing facility.

Example 18 incorporates the subject matter of any combination of Examples 14-17. In this example, the forecasting total actual demand comprises considering local power generation at the distributed computing facility.

Example 19 incorporates the subject matter of any combination of Examples 14-18. In this example, forecasting power consumption comprises forecasting power consumption in response to a job event or an energy event.

Example 20 incorporates the subject matter of any combination of Examples 14-19. In this example, the method includes adjusting total actual demand of power by the distributed computing facility by adjusting, via the processor, use of local energy generation or energy storage, or both, at the distributed computing facility.

Example 21 incorporates the subject matter of any combination of Examples 14-20. In this example, the method includes adjusting, via the processor, use of local energy generation or energy storage, or both, at the distributed computing facility in response to changing demand or changing pricing of energy, or a combination thereof.

Example 22 incorporates the subject matter of any combination of Examples 14-21. In this example, the method includes adjusting, via the processor, total actual demand of power in response to an incentive program or spot pricing of energy, or a combination thereof.

Example 23 is a non-transitory, computer-readable medium comprising instructions executable by a processor to forecast power consumption by a distributed computing facility, comprising to: forecast sequence of jobs execution on a system of the nodes over time; estimate power for the jobs of the system; and develop a system-level forecast of power of the system, wherein the system-level forecast is correlative with the sequence of job execution and the power for the jobs.

Example 24 incorporates the subject matter of Example 24. In this example, to forecast power consumption comprises to forecast power consumption in response to a job event or an energy event, wherein the job event comprises submission of a job for execution to the system, completion of a job on the system, suspension of a job on the system, or any combination thereof.

Example 25 incorporates the subject matter of any combination of Examples 23-24. In this example, the computer-readable medium includes instructions executable by the processor to adjust use of local energy generation or energy storage, or both, at the distributed computing facility in response to changing demand of power at the distributed computing facility or changing pricing of energy, or both, and wherein to forecast power consumption comprises to develop a forecast of total actual demand for the distributed computing facility.

Example 26 is an apparatus at a facility, the apparatus including means for forecasting power consumption by the facility, wherein the facility comprises a distributed computing facility having systems of compute nodes. The apparatus includes means for forecasting sequence of jobs execution on a system of the nodes over time, and means for estimating power for the jobs of the system. The apparatus also includes means for developing a system-level forecast of power of the system, wherein the system-level forecast is correlative with the sequence of job execution and the power for the jobs.

Example 27 incorporates the subject matter of Example 26. In this example, the means for developing a system-level forecast of power comprises means for developing a system-level forecast of power in response to a job event or an energy event, wherein the job event comprise submission of a job for execution to the system, completion of a job on the system, suspension of a job on the system, or any combination thereof.

Example 28 incorporates the subject matter of any combination of Examples 26-27. In this example, the apparatus includes means for adjusting use of local energy generation or energy storage, or both, at the distributed computing facility in response to changing demand of power at the distributed computing facility or changing pricing of energy, or both, and wherein the means for forecasting power comprises means for developing a forecast of total actual demand for the distributed computing facility.

Example 29 is a distributed computing facility including nodes configured to execute jobs of distributed computing. The facility includes memory storing code executable by the nodes or a processor to forecast power consumption by the distributed computing facility, comprising to: forecast sequence of jobs execution on a system of the nodes over time; estimate power for the jobs of the system; and develop a system-level power forecast of the system, wherein the system-level power forecast is correlative with the sequence of job execution and the power for the jobs.

Example 30 incorporates the subject matter of Example 29. In this example, the code is executable to activate or increase local energy generation in response to the forecast of power consumption exceeding a specified demand, and wherein the .system-level forecast comprises a predicted power profile of the system.

Example 31 incorporates the subject matter of any combination of Examples 29-30. In this example, to forecast power consumption comprises to develop a forecast of total actual demand for the distributed computing facility.

Example 32 incorporates the subject matter of any combination of Examples 29-31. In this example, to develop the forecast of total actual demand comprises considering local power generation at the distributed computing facility, and wherein the total actual demand comprises the power consumption minus an amount of local power generated at the distributed computing facility.

Example 33 incorporates the subject matter of any combination of Examples 29-32. In this example, to forecast power consumption comprises to forecast power consumption in response to a job event or an energy event, or a combination thereof.

Example 34 incorporates the subject matter of any combination of Examples 29-33. In this example, the code is executable to adjust use of local energy generation or energy storage, or both, at the distributed computing facility in response to changing demand of power or changing pricing of energy, or both.

Example 35 incorporates the subject matter of any combination of Examples 29-34. In this example, the code is executable to adjust total actual demand of power by the distributed computing facility in response to an incentive program by a utility provider or in response to spot pricing of energy, or a combination thereof.

Example 36 incorporates the subject matter of any combination of Examples 29-35. In this example, the distributed computing facility comprises a high performance computing (HPC) facility or a Big Data analytics facility, or a combination thereof.

Example 37 is a method of operating a distributed computing facility, including executing jobs of distributed computing on systems of nodes of the distributed computing facility. The method includes forecasting, via a processor, power consumption of the distributed computing facility, wherein forecasting the power consumption comprises: forecasting, via the processor, a sequence of jobs execution on a system of the nodes over time; estimating, via the processor, power for the jobs of the system; and developing, via the processor, a system-level power forecast of the system. The system-level power forecast is correlative with the sequence of job execution and the power for the jobs.

Example 38 incorporates the subject matter of Example 37. In this example, the method includes activating or increasing local energy generation at the distributed computing facility in response to a forecast of the power consumption exceeding a specified demand, and wherein the system-level forecast comprises a predicted power profile.

Example 39 incorporates the subject matter of any combination of Examples 37-38. In this example, the forecasting power consumption comprises forecasting total actual demand to a utility provider for the distributed computing facility.

Example 40 incorporates the subject matter of any combination of Examples 37-39. In this example, the forecasting power consumption comprises forecasting power consumption in response to a job event or an energy event, or both.

Example 41 incorporates the subject matter of any combination of Examples 37-40. In this example, the method includes adjusting, via the processor, total actual demand of power in response to an incentive program or spot pricing of energy, or a combination thereof.

Example 42 is a non-transitory, computer-readable medium comprising instructions executable by a processor to forecast power consumption by a distributed computing facility, comprising to: forecast sequence of jobs execution on a system of the nodes over time; estimate power for the jobs of the system; and develop a system-level forecast of power of the system. The system-level forecast is correlative with the sequence of job execution and the power for the jobs.

Example 43 incorporates the subject matter of Example 42. In this example, to forecast power consumption comprises to forecast power consumption in response to a job event, wherein the job event comprise submission of a job for execution to the system, completion of a job on the system, suspension of a job on the system, or any combination thereof.

Example 44 is a distributed computing facility having nodes configured to execute a job of distributed computing, and memory storing code executable by the nodes or a processor to forecast power consumption by the distributed computing facility. To forecast facility power consumption includes forecasting job sequence of jobs of distributed computing on a system of the nodes over time, estimate power for the jobs on the system; and develop a system-level power forecast of the system.

Example 45 incorporates the subject matter of Example 44. In this example, the system-level power forecast comprises a predicted power profile correlative with the job sequence and the power for the jobs.

Example 46 incorporates the subject matter of any combination of Examples 44-45. In this example, to forecast power consumption comprises to develop a forecast of total actual demand for the distributed computing facility.

Example 47 incorporates the subject matter of any combination of Examples 44-46. In this example, to develop the forecast of total actual demand takes into consideration the local power generation at the distributed computing facility.

Example 48 incorporates the subject matter of any combination of Examples 44-47. In this example, the total actual demand is the power consumption minus an amount of local power generated at the distributed computing facility.

Example 49 incorporates the subject matter of any combination of Examples 44-48. In this example, to forecast power consumption comprises to forecast power consumption in response to a job event or an energy event, or a combination thereof.

Example 50 is a non-transitory, computer-readable medium having instructions executable by a processor to forecast power consumption by a distributed computing facility. To forecast facility power consumption includes to forecast job sequence of jobs of distributed computing executing on a system of compute nodes over time, estimate power for the jobs of the system, and develop a system-level forecast of power of the system.

Example 51 incorporates the subject matter of Example 50. In this example, the system-level power forecast comprises a predicted power profile correlative with the job sequence and the power for the jobs.

Example 52 incorporates the subject matter of any combination of Examples 50-51. In this example, to forecast power consumption comprises to develop a forecast of total actual demand for the distributed computing facility.

Example 53 incorporates the subject matter of any combination of Examples 50-52. In this example, to develop the forecast of total actual demand comprises considering local power generation at the distributed computing facility.

Example 54 incorporates the subject matter of any combination of Examples 50-53. In this example, the total actual demand comprises the power consumption minus an amount of local power generated at the distributed computing facility.

Example 55 incorporates the subject matter of any combination of Examples 50-54. In this example, to forecast power consumption comprises to forecast power consumption in response to a job event or an energy event, or a combination thereof.

It is to be understood that specifics in the aforementioned examples may be used anywhere in one or more embodiments. For instance, all optional features of the computing device described above may also be implemented with respect to either of the methods described herein or a computer-readable medium. Furthermore, although flow diagrams and/or state diagrams may have been used herein to describe embodiments, the present techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. A distributed computing facility comprising:
nodes configured to execute a job of distributed computing; and
memory storing code executable by the nodes or a processor to forecast power consumption by the distributed computing facility, comprising to:
forecast job sequence of jobs of distributed computing on a system of the nodes over time;
estimate power for the jobs on the system; and
develop a system-level power forecast of the system.

2. The facility of claim 1, wherein the system-level power forecast comprises a predicted power profile correlative with the job sequence and the power for the jobs.

3. The facility of claim 1, wherein the code is executable to activate or increase local energy generation in response to a forecast of power consumption exceeding a specified demand.

4. The facility of claim 1, wherein to forecast power consumption comprises to develop a forecast of total actual demand for the distributed computing facility.

5. The facility of claim 4, wherein to develop the forecast of total actual demand comprises considering local power generation at the distributed computing facility.

6. The facility of claim 4, wherein the total actual demand comprises the power consumption minus an amount of local power generated at the distributed computing facility.

7. The facility of claim 1, wherein to forecast power consumption comprises to forecast power consumption in response to a job event or an energy event, or a combination thereof.

8. The facility of claim 7, wherein the job event comprise submission of a job for execution to the system, completion of a job on the system, suspension of a job on the system, or any combination thereof.

9. The facility of claim 7, wherein the energy event comprises a change in status or capacity of local generation of energy, change in capacity of local storage of energy, or change in pricing of energy beyond predefined thresholds, or any combination thereof.

10. The facility of claim 1, wherein the code is executable to adjust total actual demand of power by the distributed computing facility by adjusting use of local energy generation or energy storage, or both, at the distributed computing facility.

11. The facility of claim 1, wherein the code is executable to adjust use of local energy generation or energy storage, or both, at the distributed computing facility in response to changing demand of power or changing pricing of energy, or both.

12. The facility of claim 1, wherein the code is executable to adjust total actual demand of power by the distributed computing facility in response to an incentive program by a utility provider or in response to spot pricing of energy, or a combination thereof.

13. The facility of claim 1, wherein the distributed computing facility comprises a high performance computing (HPC) facility or a Big Data analytics facility, or a combination thereof.

14. A method of operating a distributed computing facility, comprising:
executing jobs of distributed computing on systems of nodes of the distributed computing facility;
forecasting, via a processor, power consumption of the distributed computing facility, wherein forecasting the power consumption comprises:
forecasting, via the processor, a sequence of jobs execution on a system of the nodes over time;
estimating, via the processor, power for the jobs of the system; and
developing, via the processor, a system-level power forecast of the system.

15. The method of claim 14, wherein the system-level power forecast comprises a predicted power profile correlative with the sequence of job execution and the power for the jobs.

16. The method of claim 14, comprising activating or increasing local energy generation at the distributed computing facility in response to a forecast of the power consumption exceeding a specified demand.

17. The method of claim 14, wherein forecasting power consumption comprises forecasting total actual demand to a utility provider for the distributed computing facility.

18. The method of claim 17, wherein forecasting total actual demand comprises considering local power generation at the distributed computing facility.

19. The method of claim 14, wherein forecasting power consumption comprises forecasting power consumption in response to a job event or an energy event.

20. The method of claim 14, comprising adjusting total actual demand of power by the distributed computing facility by adjusting, via the processor, use of local energy generation or energy storage, or both, at the distributed computing facility.

21. The method of claim 14, comprising adjusting, via the processor, use of local energy generation or energy storage, or both, at the distributed computing facility in response to changing demand or changing pricing of energy, or a combination thereof.

22. The method of claim 14, comprising adjusting, via the processor, total actual demand of power in response to an incentive program or spot pricing of energy, or a combination thereof.

23. A non-transitory, computer-readable medium comprising instructions executable by a processor to:
forecast power consumption by a distributed computing facility, comprising to:
forecast sequence of jobs execution on a system of the nodes over time;
estimate power for the jobs of the system; and
develop a system-level forecast of power of the system, wherein the system-level forecast is correlative with the sequence of job execution and the power for the jobs.

24. The non-transitory, computer-readable medium of claim 23, wherein to forecast power consumption comprises to forecast power consumption in response to a job event or an energy event, wherein the job event comprises submission of a job for execution to the system, completion of a job on the system, suspension of a job on the system, or any combination thereof.

25. The non-transitory, computer-readable medium of claim 23, comprising instructions executable by the processor to adjust use of local energy generation or energy storage, or both, at the distributed computing facility in response to changing demand of power at the distributed computing facility or changing pricing of energy, or both, and wherein to forecast power consumption comprises to develop a forecast of total actual demand for the distributed computing facility.
